(19) United States
(12) Patent Application Publication
(10) Pub. No.: US 2026/0282174 A1
(43) Pub. Date: Sep. 17, 2026

(54) OPTICAL SENSOR COVER AND OPTICAL SENSOR

(71) Applicant: AGC Inc., Tokyo (JP)

(72) Inventors: Sanae ENDO, Tokyo (JP); Naoto TATSUOKA, Tokyo (JP)

(73) Assignee: AGC Inc., Tokyo (JP)

(21) Appl. No.: 19/675,210

(22) Filed: May 12, 2026

Related U.S. Application Data
(63) Continuation of application No. PCT/JP2024/037854, filed on Oct. 24, 2024.

(30) Foreign Application Priority Data
Nov. 13, 2023 (JP) 2023-193052

(51) Int. Cl. H05B 3/86; G01S 7/481; G01S 17/08; H05B 3/00; H05B 3/12; H05B 3/20

(52) U.S. Cl. CPC H05B 3/86; G01S 7/4813; G01S 17/08; H05B 3/0014; H05B 3/12; H05B 3/20

(57) ABSTRACT

An optical sensor cover comprises an optically-transparent substrate and a linear heating element provided in the substrate. The heating element comprises a plurality of wiring segments arranged in an in-plane direction of the substrate and partitioned by a plurality of imaginary square lattice cells each having one side of 10 mm. The plurality of wiring segments include a first and a second wiring segment. The first wiring segment is a wiring segment including a position where a distance from an edge of the substrate is ≤20 mm.

The second wiring segment is a wiring segment including no position where a distance from the edge is ≤20 mm, or, if none exists, a wiring segment including a position farthest from the edge. L′n/Ln and L′m/Lm are lower than 1.2. Rn/Ln of 50% or more of all first wiring segments is lower than Rm/Lm of the second wiring segment.

### INCORPORATION BY REFERENCE

This application is based upon and claims the benefit of priority from Japanese patent application No. 2023-193052, filed on Nov. 13, 2023, and PCT application No. PCT/JP2024/037854 filed on Oct. 24, 2024, the disclosure of which is incorporated herein in its entirety by reference.

### BACKGROUND

The present disclosure relates to an optical sensor cover and an optical sensor.

An optical sensor such as a range sensor for measuring a distance to an object, comprising a light projecting unit for projecting near-infrared light to the object, and an optical element such as a light receiving unit for receiving reflected light reflected on the object has been known. The optical sensor comprises an optical sensor cover for protecting optical elements disposed inside thereof. Patent Literature 1 discloses a heating system for removing condensation formed on an optical sensor cover (see, for example, Patent Literature 1).

[Patent Literature 1] U.S. Pat. No. 10,588,178

### SUMMARY

The heating system disclosed in Patent Literature 1 heats the surface of the optical sensor cover by making an electric current flow through a transparent conductive film extending between a pair of busbar electrodes provided in the optical sensor cover. However, the transparent conductive film covers a light passing area in the optical sensor cover and absorbs near-infrared light. As a result, the optical transmittance of the optical sensor cover is lowered.

The present disclosure provides an optical sensor cover and an optical sensor capable of suppressing the reduction in the optical transmittance thereof.

An optical sensor cover according to a first aspect comprises:
an optically-transparent substrate; and
a linear heating element provided in the substrate, wherein
the heating element comprises a plurality of wiring segments arranged in an in-plane direction of the substrate and partitioned by a plurality of imaginary square lattice cells each having one side of 10 mm,
the plurality of wiring segments include a first wiring segment and a second wiring segment,
the first wiring segment is a wiring segment including a position at a distance of 20 mm or shorter from an edge of the substrate, of which L′n/Ln is lower than 1.2, where L′n is an actual length of the first wiring segment, and Ln is a length of the first wiring segment measured with coarse graining of 10 mm,
the second wiring segment is, among wiring segments other than the first wiring segment, a wiring segment including no position at a distance of 20 mm or shorter from the edge of the substrate, of which L′m/Lm is lower than 1.2, where L′m is an actual length of the second wiring segment, and Lm is a length of the second wiring segment measured with coarse graining of 10 mm; or the second wiring segment is, when there is no wiring segment including no position at a distance of 20 mm or shorter from the edge of the substrate among the wiring segments other than the first wiring segment, a wiring segment including a position farthest from the edge of the substrate among the wiring segments other than the first wiring segment, of which L′m/Lm is lower than 1.2, and
when a resistance value of the first wiring segment is represented by Rn; an average resistance value of the first wiring segment is defined as Rn/Ln; a resistance value of the second wiring segment is represented by Rm; and an average resistance value of the second wiring segment is defined as Rm/Lm,
the average resistance value Rn/Ln of 50% or more of all first wiring segments is lower than the average resistance value Rm/Lm of the second wiring segment.

An optical sensor cover according to a second aspect comprises:
an optically-transparent substrate; and
a linear heating element provided in the substrate, wherein
the heating element comprises a plurality of wiring segments arranged in an in-plane direction of the substrate and partitioned by a plurality of imaginary square lattice cells each having one side of 10 mm,
the plurality of wiring segments includes a third wiring segment and a second wiring segment,
the third wiring segment is a wiring segment of which L′k/Lk is equal to or higher than 1.2, where L′k is an actual length of the third wiring segment, and Lk is a length of the third wiring segment measured with coarse graining of 10 mm, and
the second wiring segment is, among wiring segments other than the third wiring segment, a wiring segment including no position at a distance of 20 mm or shorter from the edge of the substrate, of which L′m/Lm is lower than 1.2, where L′m is an actual length of the second wiring segment, and Lm is a length of the second wiring segment measured with coarse graining of 10 mm; or the second wiring segment is, when there is no wiring segment including no position at a distance of 20 mm or shorter from the edge of the substrate among the wiring segments other than the third wiring segment, a wiring segment including a position farthest from the edge of the substrate among the wiring segments other than the third wiring segment, of which L′m/Lm is lower than 1.2, and
when a resistance value of the third wiring segment is represented by Rk; an average resistance value of the third wiring segment is defined as Rk/L′k; a resistance value of the second wiring segment is represented by Rm; and an average resistance value of the second wiring segment is defined as Rm/Lm,
the average resistance value Rk/L′k of 50% or more of all third wiring segments is lower than the average resistance value Rm/Lm of the second wiring segment.

An optical sensor cover according to a third aspect is one according to the first aspect, wherein the first wiring segment may include at least one curved part.

An optical sensor cover according to a fourth aspect is one according to second aspect, wherein the third wiring segment may include at least one curved part.

An optical sensor cover according to a fifth aspect is one according to the first or third aspect, wherein the average resistance value Rn/Ln of the first wiring segment may be 0.3 to 0.95 times the average resistance value Rm/Lm of the second wiring segment.

An optical sensor cover according to a sixth aspect is one according to the second or fourth aspect, wherein the average resistance value Rk/L′k of the third wiring segment may be 0.3 to 0.95 times the average resistance value Rm/L′m of the second wiring segment.

An optical sensor cover according to a seventh aspect is one according to any one of the first, third, and fifth aspects, wherein the first wiring segment may include an area having a line width larger than the average line width of the heating element.

An optical sensor cover according to an eighth aspect is one according to any one of the second, fourth, and sixth aspects, wherein the third wiring segment may include an area having a line width larger than the average line width of the heating element.

An optical sensor cover according to a ninth aspect is one according to any one of the first to eighth aspects, wherein the heating element may contain at least one of gold, silver, copper, tin, aluminum, and an alloy using them.

An optical sensor according to a tenth aspect comprises:
a housing;
an optical element housed in the housing; and
an optical sensor cover attached to the housing so as to cover the optical element, wherein
the optical sensor cover comprises:
an optically-transparent substrate; and
a linear heating element provided in the substrate, wherein
the heating element comprises a plurality of wiring segments arranged in an in-plane direction of the substrate and partitioned by a plurality of imaginary square lattice cells each having one side of 10 mm,
the plurality of wiring segments include a first wiring segment and a second wiring segment,
the first wiring segment is a wiring segment including a position at a distance of 20 mm or shorter from an edge of the substrate, of which L′n/Ln is lower than 1.2, where L′n is an actual length of the first wiring segment, and Ln is a length of the first wiring segment measured with coarse graining of 10 mm,
the second wiring segment is, among wiring segments other than the first wiring segment, a wiring segment including no position at a distance of 20 mm or shorter from the edge of the substrate, of which L′m/Lm is lower than 1.2, where L′m is an actual length of the second wiring segment, and Lm is a length of the second wiring segment measured with coarse graining of 10 mm; or the second wiring segment is, when there is no wiring segment including no position at a distance of 20 mm or shorter from the edge of the substrate among the wiring segments other than the first wiring segment, a wiring segment including a position farthest from the edge of the substrate among the wiring segments other than the first wiring segment, of which L′m/Lm is lower than 1.2, and
when a resistance value of the first wiring segment is represented by Rn; an average resistance value of the first wiring segment is defined as Rn/Ln; a resistance value of the second wiring segment is represented by Rm; and an average resistance value of the second wiring segment is defined as Rm/Lm,
the average resistance value Rn/Ln of 50% or more of all first wiring segments is lower than the average resistance value Rm/Lm of the second wiring segment.

An optical sensor according to an eleventh aspect comprises:
a housing;
an optical element housed in the housing; and
an optical sensor cover attached to the housing so as to cover the optical element, wherein
the optical sensor cover comprises:
an optically-transparent substrate; and
a linear heating element provided in the substrate, wherein
the heating element comprises a plurality of wiring segments arranged in an in-plane direction of the substrate and partitioned by a plurality of imaginary square lattice cells each having one side of 10 mm,
the plurality of wiring segments includes a third wiring segment and a second wiring segment,
the third wiring segment is a wiring segment of which L′k/Lk is equal to or higher than 1.2, where L′k is an actual length of the third wiring segment, and Lk is a length of the third wiring segment measured with coarse graining of 10 mm, and;
the second wiring segment is, among wiring segments other than the third wiring segment, a wiring segment including no position at a distance of 20 mm or shorter from the edge of the substrate, of which L′m/Lm is lower than 1.2, where L′m is an actual length of the second wiring segment, and Lm is a length of the second wiring segment measured with coarse graining of 10 mm; or the second wiring segment is, when there is no wiring segment including no position at a distance of 20 mm or shorter from the edge of the substrate among the wiring segments other than the third wiring segment, a wiring segment including a position farthest from the edge of the substrate among the wiring segments other than the third wiring segment, of which L′m/Lm is lower than 1.2, and
when a resistance value of the third wiring segment is represented by Rk; an average resistance value of the third wiring segment is defined as Rk/L′k; a resistance value of the second wiring segment is represented by Rm; and an average resistance value of the second wiring segment is defined as Rm/Lm, the average resistance value Rk/L′k of 50% or more of all third wiring segments is lower than the average resistance value Rm/Lm of the second wiring segment.

An optical sensor according to a twelfth aspect is one according to the tenth or eleventh aspect, wherein
the housing is made of resin or metal, and
when the housing is made of metal, a heat insulating material may be provided between the housing and the substrate.

An optical sensor according to a thirteenth aspect is one according to any one of the tenth to twelfth aspects, wherein
the optical sensor may be a range sensor, and
the optical element may comprise a light projecting unit, and a light receiving unit configured to receive reflected light, the reflected light being light projected from the light projecting unit and reflected on an object.

According to the present disclosure, it is possible to provide an optical sensor cover and an optical sensor capable of suppressing the reduction in the optical transmittance thereof.

The above and other objects, features and advantages of the present disclosure will become more fully understood from the detailed description given hereinbelow and the accompanying drawings.

### BRIEF DESCRIPTION OF DRAWINGS

FIG. 1 is a perspective view schematically showing an example of a configuration of an optical sensor according to a first embodiment;

FIG. 2 is a cross-sectional view of an optical sensor cover of the optical sensor according to the first embodiment, taken along a line A-A shown in FIG. 1;

FIG. 3 is a front view of the optical sensor cover in the optical sensor according to the first embodiment;

FIGS. 4A and 4B show schematic diagrams for explaining specific examples of lengths measured with coarse graining of 10 mm;

FIG. 5 is a front view of an optical sensor cover in an optical sensor according to a second embodiment;

FIGS. 6A and 6B show examples of wiring segments provided in a heating element in the optical sensor cover of the optical sensor according to the second embodiment;

FIGS. 7A and 7B show results of simulations of temperature distributions on substrates of covers for optical sensors in the optical sensors according to the first and second embodiments;

FIG. 8 is a front view of an optical sensor cover in an optical sensor according to a third embodiment; and

FIGS. 9A and 9B show results of simulations of the temperature distributions of substrates of covers for optical sensors in the optical sensors according to according to the third embodiment.

### DESCRIPTION OF EMBODIMENTS

Embodiments will be described hereinafter with reference to the drawings. Note that for ease of understanding, the scale of each component or the like in the drawings may differ from the actual scale. Regarding the directions such as parallel, right angle, orthogonal, horizontal, vertical, up, down, left, and right, deviations to such a degree that the effect of embodiments is not impaired are allowed. The shapes of corners are not limited to right angles, but they may be roundish. The parallel, right angle, orthogonal, horizontal, and vertical may include roughly parallel, roughly right angle, roughly orthogonal, roughly horizontal, and roughly vertical, respectively.

In this specification, a three-dimensional orthogonal coordinate system having three axial directions (X, Y, and Z axis directions) is used; the width direction or the crosswise direction of the optical sensor cover is defined as the X axis direction; the height direction or the vertical direction of the optical sensor cover is defined as the Y axis direction; and the thickness direction of the optical sensor cover is defined as the Z axis direction. The side toward which an arrow in the X axis direction points is defined as the +X axis direction, and the opposite side is defined as the −X axis direction. The side toward which an arrow in the Y axis direction points is defined as the +Y axis direction, and the opposite side is defined as the −Y axis direction.

The side toward which an arrow in the Z axis direction points is defined as the +Z axis direction, and the opposite side is defined as the −Z axis direction.

The X, Y, and Z axis directions represent a direction parallel to the X axis, a direction parallel to the Y axis, and a direction parallel to the Z axis, respectively. The X, Y, and Z axis directions are orthogonal to each other. A direction parallel to the X axis direction or a direction parallel to the Y axis direction may be referred to as an in-plane direction. A direction parallel to the Z axis direction may be referred to as a plane-perpendicular direction. The XY, YZ, and ZX planes represent an imaginary plane parallel to the X and Y axis directions, an imaginary plane parallel to the Y and Z axis directions, and an imaginary plane parallel to the Z and X axis directions, respectively.

### First Embodiment

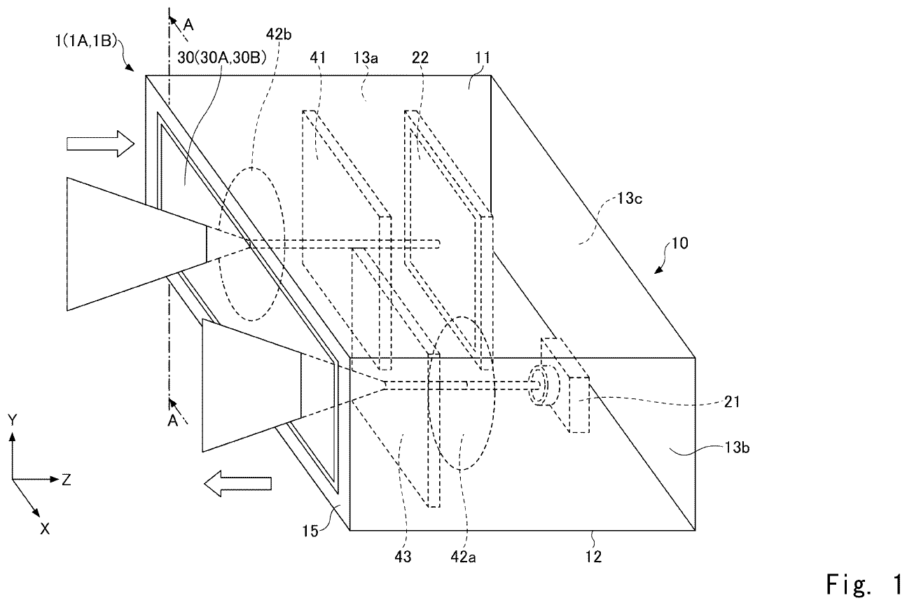

An optical sensor 1 according to a first embodiment will be described. FIG. 1 is a perspective view schematically showing an example of the optical sensor 1 according to the first embodiment. The optical sensor 1 is a range sensor for measuring a distance to an object. However, the optical sensor 1 is not limited to range sensors, and may be other types of optical sensors. Examples of other types of optical sensors include a photographing apparatus such as a camera that is provided in a mobile body such as a vehicle and photographs an object outside the mobile body. Note that in this specification, a symbol “-”, which indicates a range of numerical values, means that values in front of and behind this symbol are included in the range as lower and upper limit values, respectively.

### <Optical Sensor 1>

As shown in FIG. 1, the optical sensor 1 comprises a housing 10, an optical element including a light projecting unit 21 and a light receiving unit 22, and an optical sensor cover 30. Further, the optical sensor 1 comprises optical members such as an optical filter 41, lenses 42a and 42b, and a diffusion plate 43. Further, the optical sensor 1 comprises an electronic circuit such as a range finding circuit for measuring a distance to an object based on a light-receiving signal received from the light receiving unit 22.

### <Housing 10>

The housing 10 comprises an upper surface 11 positioned on the +Y axis direction side, a bottom surface 12 positioned on the −Y axis direction side, and three side surfaces 13a, 13b and 13c connecting the upper surface 11 with the bottom surface 12. The housing 10 has a rectangular parallelepiped shape, but is not limited thereto. The housing 10 may have other shapes such as a cubic shape, a spherical shape, and an ellipsoidal shape.

The housing 10 houses the light projecting unit 21, the light receiving unit 22, the optical filter 41, the lenses 42a and 42b, and the diffusion plate 43. Further, the housing 10 according to this embodiment includes an opened area for holding the optical sensor cover 30 on the −Z axis direction side.

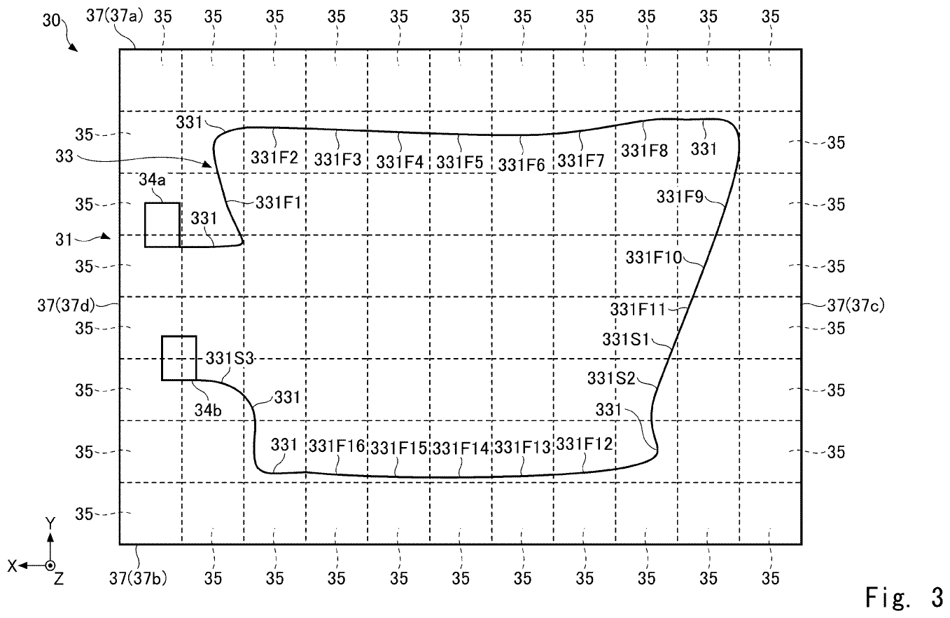

There is no restriction on the material of which the housing 10 is made. Examples of the material of which the housing 10 is made include resins and metals. It should be noted that in order to remove condensation, frost, snow and the like (hereinafter referred to as “condensation and the like”) formed or deposited on the surface of the optical sensor cover 30, the surface of the optical sensor cover 30 is heated by making a linear heating element 33 (see FIG. 3) provided in the optical sensor cover 30 generate heat. In the case where the housing 10 is made of a material having a high thermal conductivity such as metal, if the optical sensor cover 30 is directly fitted into the opened area of the housing 10, the heat of the optical sensor cover 30 is dissipated into the housing 10, so that the function of removing condensation and the like may be impaired. In order to prevent the function of removing condensation and the like from being impaired, the housing 10 preferably further comprises a heat insulating material 15. Although the position of the heat insulating material 15 is arbitrarily determined, it is preferably disposed between the edge of the opened area of the housing 10 and the optical sensor cover 30.

### <Optical Element>

The light projecting unit 21 in this embodiment is a light emitting element(s) such as a semiconductor laser or an LED(s) (Light Emitting Diode(s)) that projects (i.e., emits) near-infrared light. The light projecting unit 21 projects near-infrared light. The near-infrared light passes through the lens 42a, the diffusion plate 43, and the optical sensor cover 30, and is projected onto an external object. However, depending on the type of the optical sensor 1, the light projecting unit 21 projects light belonging to other wavelength ranges such as visible light. Note that in this specification, “near-infrared light” refers to light belonging to a wavelength range of 800 nm to 2,500 nm.

The light receiving unit 22 in this embodiment is a light receiving element such as a photodiode, a CCD (Charge Coupled Device), or a CMOS (Complementary Metal Oxide Semiconductor). The near-infrared light projected from the light projecting unit 21 is reflected by the object and then returns to the optical sensor 1. The light receiving unit 22 receives the reflected light (near-infrared light) that has passed through each of the optical sensor cover 30, the lens 42b, and the optical filter 41. The light receiving unit 22 outputs a light-receiving signal derived from the reflected light to a signal processing unit such as a range finding circuit.

### <Optical Sensor Cover 30>

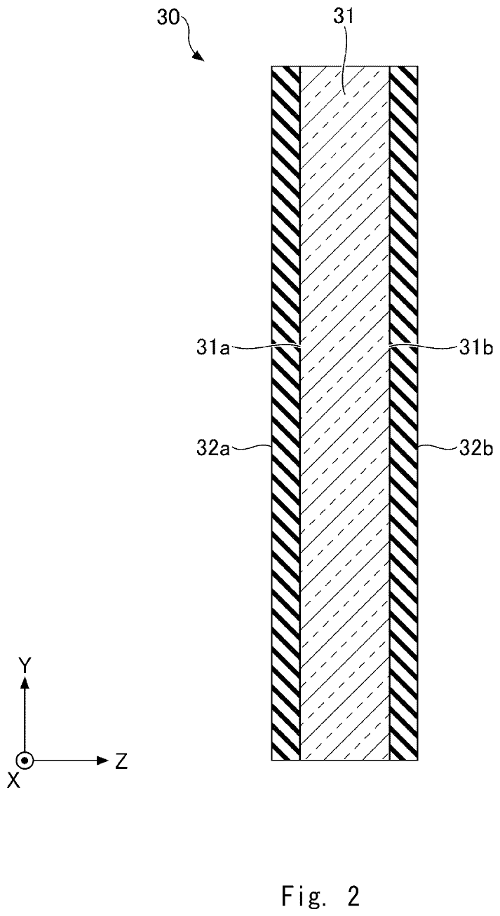

The configuration of the optical sensor cover 30 will be described with reference to FIGS. 2 and 3. FIG. 2 is a cross-sectional view of the optical sensor cover 30 taken along a line A-A shown in FIG. 1. Further, FIG. 3 is a diagram of the optical sensor cover 30 viewed from the +Z axis direction side. Note that a view in which an object such as the optical sensor cover 30 is viewed from the +Z direction side is referred to as a “front view”.

As shown in FIG. 2, the optical sensor cover 30 comprises an optically-transparent substrate 31. The substrate 31 in this embodiment is a glass substrate that lets near-infrared light pass therethrough. Examples of types of glasses include alkali-free borosilicate glass, borosilicate glass, soda-lime glass, high-silica glass, and other oxide-based glasses containing silicon oxide as a main component.

The substrate 31 preferably blocks visible light in order to prevent the inside of the housing 10 from being visible from the outside. However, depending on the type of the optical sensor 1, the substrate 31 may be one that lets visible light pass therethrough. The substrate 31 in this embodiment is a plate-like member disposed parallel to the XY plane. However, the substrate 31 may be one having a curved surface.

The optical sensor cover 30 further comprises a plurality of optical thin films 32a and 32b bonded to the main surface 31a (hereinafter referred to as the “outer surface 31a”) of the substrate 31 on the-Z axis direction side and the main surface 31b (hereinafter referred to as the “inner surface 31b”) thereof on the +Z axis direction side, respectively. Each of the optical thin films 32a and 32b in this embodiment is an antireflection film that prevents the reflection of near-infrared light. However, the type of the optical thin films 32a and 32b is not limited to antireflection films.

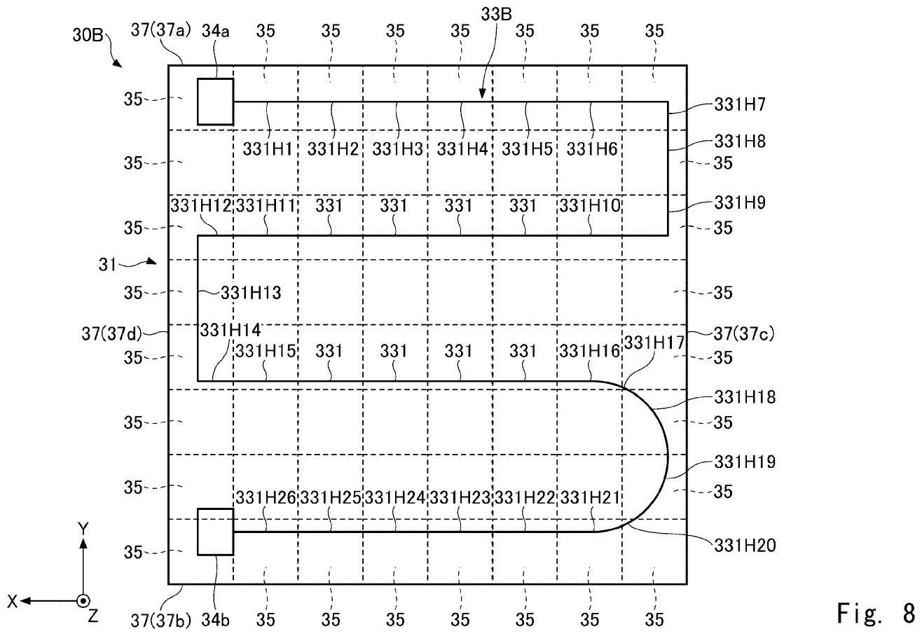

The optical sensor cover 30 is required to have a high optical transmittance. However, when condensation and the like are formed or deposited on the outer surface 31a of the substrate 31 or the optical thin film 32a, the optical transmittance is lowered. Therefore, the optical sensor cover 30 comprises a linear heating element 33 (hereinafter simply referred to as the “heating element 33”) for heating the substrate 31 in order to remove the condensation and the like. Further, the optical sensor cover 30 comprises a pair of electrodes 34a and 34b for feeding an electric current to the heating element 33. The heating element 33 in this embodiment is a roughly circumferential member extending from the electrode 34a to the electrode 34b. However, the heating element 33 is not limited to those having a roughly circumferential shape. The heating element 33 may have, for example, one having a folded structure. The folded structure will be described later with reference to FIG. 8. However, regardless of what kind of shape the heating element 33 has, the area where the heating element 33 and the substrate 31 overlap each other in the front view is equal to or smaller than 3% of the total area of the substrate 31. When the area is equal to or smaller than 3%, it is possible to make the influence of the heating element 33 on the transmitted light roughly negligible.

A pair of electrodes 34a and 34b are connected to both ends of the heating element 33, respectively. For example, when the electrode 34a is a positive electrode and the electrode 34b is a negative electrode, an electric current flows from the electrode 34a to the electrode 34b through the heating element 33. On the other hand, when the electrode 34a is a negative electrode and the electrode 34b is a positive electrode, an electric current flows from the electrode 34b to the electrode 34a through the heating element 33. As an electric current flows through the heating element 33, the heating element 33 generates heat. As a result, the substrate 31 is heated.

The heating element 33 and the electrodes 34a and 34b in this embodiment are all provided on the inner surface 31b of the substrate 31. However, the positions of the heating element 33 and the electrodes 34a and 34b are not limited to this example. Further, the material of which the heating element 33 is made is a conductive material such as metal. Examples of the material of which the heating element 33 is made include gold, silver, copper, tin, aluminum, and an alloy using them.

Since the heating element 33 has a linear shape, the area where the heating element 33 and the substrate 31 overlap each other can be reduced as compared with a planar heating element such as a transparent conductive film. That is, the heating element 33 makes it possible to secure a wide near-infrared light passage area in the substrate 31. As a result, the reduction in the optical transmittance of the optical sensor cover 30 is reduced. Further, the heating element 33 is disposed at a position close to the edge 37 of the substrate 31 in order to increase the near-infrared light passage area in the substrate 31.

The heating element 33 is formed of a plurality of wiring segments 331. The plurality of wiring segments 331 are partitioned from each other by using a plurality of imaginary square lattice cells 35 arranged in the in-plane direction of the substrate 31. For example, the plurality of imaginary square lattice cells 35 are arranged in a matrix pattern in both the X and Y axis directions. In FIG. 3, reference numerals 35 are added to only four peripheral sides of the substrate 31, but lattice cells indicated by broken lines inside them are also imaginary square lattice cells 35.

The plurality of imaginary square lattice cells 35 are not square lattice cells that actually appear in the substrate 31, but are imaginarily-defined square lattice cells. Each of the plurality of imaginary square lattice cells 35 is an imaginary square lattice cell having one side of 10 mm. In this embodiment, one side of the imaginary square lattice cell 35 along the X axis direction is 10 mm, and one side thereof along the Y axis direction is also 10 mm. However, the reference point (or the base point) for determining the position of each imaginary square lattice cell 35 (e.g., the position of the center of each imaginary square lattice cell 35) (e.g., the origin of the XY coordinate system) is arbitrarily determined. Further, an angle between one side of the imaginary square lattice cell 35 and the X or Y axis direction is arbitrarily determined.

Each of the plurality of wiring segments 331 is continuous with wiring segments 331 adjacent thereto. That is, each of the plurality of wiring segments 331 is connected in series with wiring segments 331 adjacent thereto. The boundary of each of the plurality of wiring segments 331 is defined by one side of the imaginary square lattice cell 35. Therefore, the boundary of each of the plurality of wiring segments 331 is not one visible from the outside but is an imaginary one.

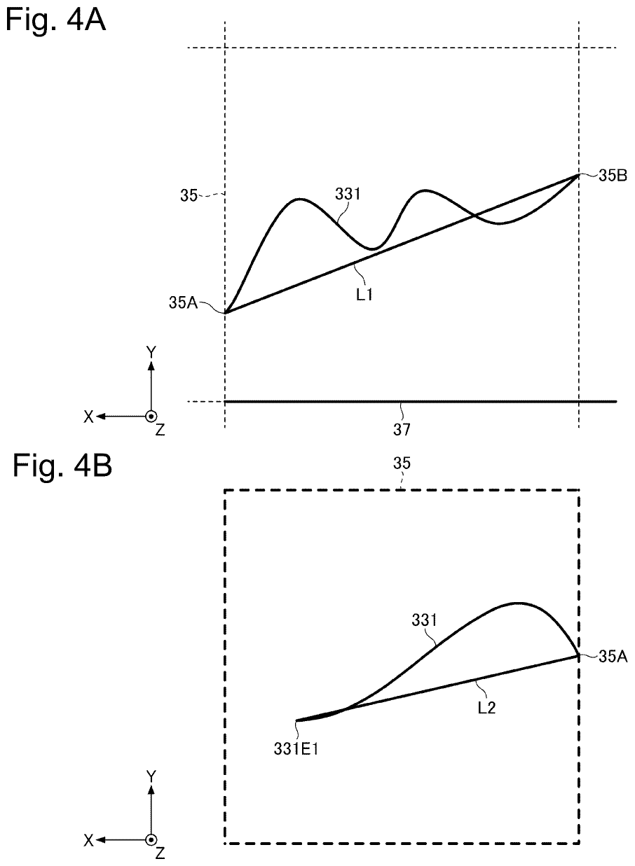

The plurality of wiring segments 331 includes wiring segments 331 disposed at a distance of 20 mm or shorter from the edge 37 of the substrate 31. Among them, the wiring segments 331 described below are referred to as “first wiring segments”. That is, the first wiring segment (i.e., each of the first wiring segments) is a wiring segment 331 of which L′n/Ln is lower than 1.2, where L′n is an actual length of the first wiring segment, and Ln is a length of the first wiring segment measured with coarse graining of 10 mm. In the case of FIG. 3, among the plurality of wiring segments 331, wiring segments 331F1, 331F2, 331F3, . . . , 331F16 correspond to the first wiring segments. Hereinafter, the wiring segments 331 corresponding to the first wiring segments are generically referred to as “first wiring segments 331F” . The “length measured with coarse graining of 10 mm” will be described later with reference to FIGS. 4A and 4B. “L′n/Ln” means a value obtained by dividing the actual length L′n by the length Ln of the first wiring segment measured with coarse graining of 10 mm. That is, in this specification, a term including “/” means a value obtained by dividing an arbitrary numerical value by another numerical value. For example, “A/B” means a value obtained by dividing a numerical value A by a numerical value B. The same applies to terms including “/” in the following description.

The wiring segments 331 includes “second wiring segments” in addition to the “first wiring segments” described above. The second wiring segment (i.e., each of the second wiring segments) is, among the wiring segments 331 other than the first wiring segments 331F, a wiring segment 331 including no position at a distance of 20 mm or shorter from the edge 37 of the substrate 31, of which L′m/Lm is lower than 1.2, where L′m is the actual length of the second wiring segment, and Lm is a length of the second wiring segment measured with coarse graining of 10 mm. In the case of FIG. 3, wiring segments 331S1 and 331S2 correspond to the second wiring segments. Further, the second wiring segment is, when there is no wiring segment 331 including no position at a distance of 20 mm or shorter from the edge 37 of the substrate 31 among the wiring segments 331 other than the first wiring segments 331F (e.g., when the heating element 33 is wired so that there is no wiring segment 331S1 nor 331S2 shown in FIG. 3), a wiring segment 331 including a position farthest from the edge 37 of the substrate 31 among the wiring segments 331 other than the first wiring segments 331F, of which L′m/Lm is lower than 1.2. Note that the “wiring segments 331 including a position farthest from the edge 37 of the substrate 31” refers to a wiring segments 331 of which, when a distance from each of the wiring segments 331 other than the first wiring segments 331F to the nearest edge 37 is measured, the distance is the longest. The same applies to the other embodiments. For example, the wiring segments 331S3 shown in FIG. 3 corresponds to the second wiring segment.

The edge 37 of the substrate 31 may be the upper edge 37a of the substrate 31 positioned on the +Y axis direction side thereof, or the lower edge 37b of the substrate 31 positioned on the −Y axis direction side thereof. Further, the edge 37 of the substrate 31 may be the right edge 37c of the substrate 31 positioned on the −X axis direction side thereof, or the left edge 37d of the substrate 31 positioned on the +X axis direction side thereof.

### <Average Resistance Value of Divided Wiring Line 331>

In the heating element 33, when no special contrivance is made for the shape and the line width of each of the wiring segments 331, the heat-generating density in the substrate 31 may become uneven due to the difference in the position of each wiring segment 331 and the wiring density (the length of the wiring segments 331 included in the imaginary square lattice cell 35 in the front view), so that the temperature may become uneven in the substrate 31.

In particular, the peripheral area of the first wiring segments 331F disposed near the edge 37 may become a hot spot where the temperature locally rises because the movement of the heat flow diffusing from these first wiring segments 331F is hindered by the edge 37. Further, since the optical sensor cover 30 is a member facing the outside, it is not desirable if a hot spot is formed on the outer side of the substrate 31. Therefore, it is desirable to suppress the formation of a hot spot on the outer side of the substrate 31. Note that a heating element 33 in which no special contrivance is made for the shape and the line width of each of wiring segments 331 is referred to as a “heating element in related art”.

As the first wiring segments 331F have a configuration described below, it is possible to suppress the formation of a hot spot in the substrate 31. Specifically, the average resistance value Rn/Ln of 50% or more of all the first wiring segments 331F is lower than the average resistance value Rm/Lm of the second wiring segment. Further, the average resistance value Rn/Ln of 90% or less of all the first wiring segments 331F may be lower than the average resistance value Rm/Lm of the second wiring segment. In order to make the average resistance value Rn/Ln of 50% or more of the first wiring segments 331F lower than the average resistance value Rm/Lm of the second wiring segment, the shape and the line width of the corresponding first wiring segments 331F are adjusted. Note that the average resistance value Rn/Ln of the first wiring segment 331F and the average resistance value Rm/Lm of the second wiring segment will be described later. The method for adjusting the shape and the line width of each of the first wiring segments 331F is arbitrarily determined. Its examples include a method for reducing the number of curved parts of the first wiring segments 331F, a method for reducing the wiring density by reducing the curvature of curved parts thereof, and a method for making the line width of the first wiring segments 331F larger than the average line width of the heating element 33.

Referring to FIGS. 4A and 4B, specific examples of the “length measured with coarse graining of 10 mm” in the wiring segment 331 will be described. FIGS. 4A and 4B is schematic diagrams for explaining the specific examples of the length measured with coarse graining of 10 mm. Hereinafter, the “length measured with coarse graining of 10 mm” will be referred to as a “coarse-graining length”.

In order to measure the coarse-graining length of the wiring segment 331, a plurality of imaginary square lattice cells each having one side of 10 mm are arranged on the XY plane. These imaginary square lattice cells are referred to as “imaginary square lattice cells for measuring a coarse-graining length”. The imaginary square lattice cells for measuring the coarse-graining length are the same square lattice cells as the imaginary square lattice cells 35 for partitioning the wiring segments 331. In the following description, the imaginary square lattice cells for measuring the coarse-graining length are referred to as the “imaginary square lattice cells 35”.

FIG. 4A shows one imaginary square lattice cell 35 and one wiring segment 331 (first wiring segment 331F or second wiring segment) included in this one imaginary square lattice cell 35. Firstly, the length of a straight line LI connecting intersections 35A and 35B between the imaginary square lattice cell 35 and the wiring segment 331 is measured. The intersections 35A and 35B correspond to both ends of the wiring segment 331. The straight line LI corresponds to a line segment connecting both ends of the wiring segment 331. The length of the straight line LI corresponds to the coarse-graining length of the wiring segment 331. Note that although the imaginary square lattice cell 35 shown in FIGS. 4A and 4B are an imaginary square lattice cell 35 including one side (bottom side) which overlaps with a part of the edge 37 of the substrate 31, the coarse-graining lengths of the wiring segments 331 partitioned by the other imaginary square lattices 35 are also measured in a similar manner. Further, the intersections 35A and 35B between the imaginary square lattice cell 35 and the wiring segment 331 may be those which respectively intersect arbitrary two sides of the imaginary square lattice cell 35.

As shown in FIG. 4B, when the wiring segment 331 and the imaginary square lattice cell 35 intersect only at one point, a straight line L2 connecting the intersection 35A between the wiring segment 331 and the imaginary square lattice cell 35 and the end 331E1 of the wiring segment 331 which does not intersect the imaginary square lattice cell 35 may be used as the coarse-graining length.

In this embodiment, the average resistance value of each first wiring segment 331F is a resistance value defined as “Rn/Ln” by using the resistance value Rn of the first wiring segment 331F and the coarse-graining length Ln of the first wiring segment 331F. The resistance value Rn of the first wiring segment 331F is obtained, for example, from the potential difference between both ends of the first wiring segment 331F and the electric current value of the electric current flowing through the first wiring segment 331F, measured at the wiring temperature of 20° C. to 30° C. Note that the potential difference between both ends of the first wiring segment 331F and the electric current value are obtained by specifying places corresponding to the positions of both ends of the first wiring segment 331F based on coordinate information such as the X and Y axis coordinates, and then measuring the potential difference between both specified places and the electric current value.

In this embodiment, when the resistance value of the second wiring segment is represented by Rm; the coarse-graining length of the second wiring segment is represented by Lm; and the average resistance value of the second wiring segment is defined as Rm/Lm (m is a natural number), the average resistance value Rn/Ln of 50% or more of the first wiring segments 331F is smaller than the average resistance value Rm/Lm of the second wiring segment. Further, the average resistance value Rn/Ln of 50% or more of the first wiring segments 331F is preferably 0.01 to 0.99 times and more preferably 0.3 to 0.95 times the average resistance value Rm/Lm of the second wiring segment. By adjusting the relative value of the average resistance value Rn/Ln to Rm/Lm to the aforementioned range, it is possible to suppress the formation of a hot spot in the substrate 31 more effectively. When there are a plurality of second wiring segments, the above-described matter holds for each m.

In contrast, when the average resistance value Rn/Ln of 50% or more of the first wiring segments 331F is lower than 0.01 times the value Rm/Lm, the average resistance value Rn/Ln of the first wiring segments 331F is too small, so that the temperature of the peripheral area of the first wiring segments 331F may be low relative to the average temperature of the substrate 31. Further, when the average resistance value Rn/Ln of 50% or more of the first wiring segments 331F exceeds 0.99 times the average resistance value Rm/Lm of the heating element 33, the formation of a hot spot may not be sufficiently suppressed.

### Second Embodiment

An optical sensor 1A according to a second embodiment will be described. Note that in the second embodiment, components similar to those of the first embodiment are denoted by the same reference numerals, and their descriptions will be omitted.

Similarly to the first embodiment (see FIG. 1), the optical sensor 1A according to the second embodiment comprises a housing 10 and an optical element including a light projecting unit 21 and a light receiving unit 22. Further, the optical sensor 1A according to the second embodiment comprises an optical sensor cover 30A. Similarly to the optical sensor cover 30 according to the first embodiment, the optical sensor cover 30A is a member for protecting the optical element housed in the housing 10. The linear heating element 33A (hereinafter simply referred to as a “heating element 33A”) in the optical sensor cover 30A is different from that in the first embodiment.

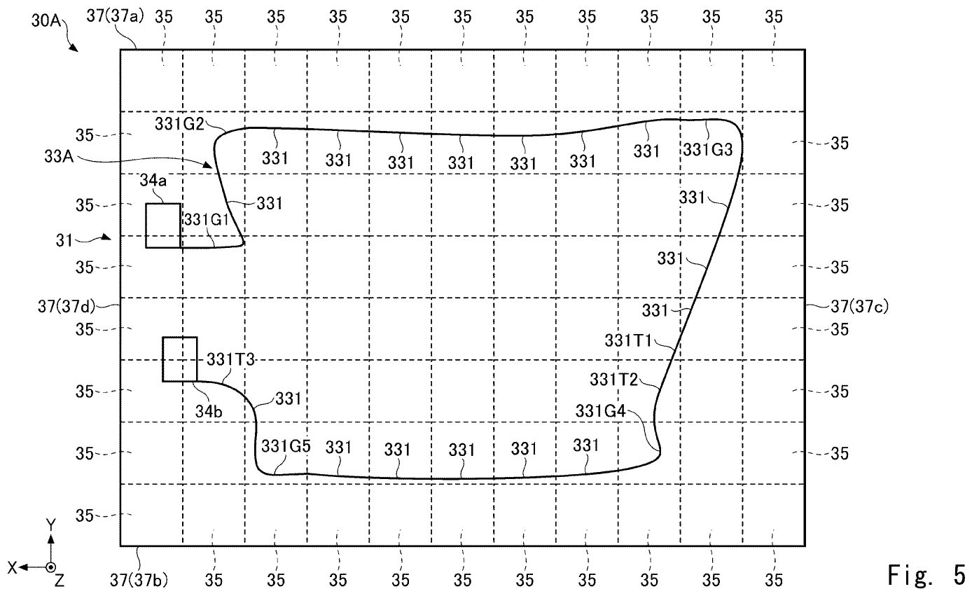

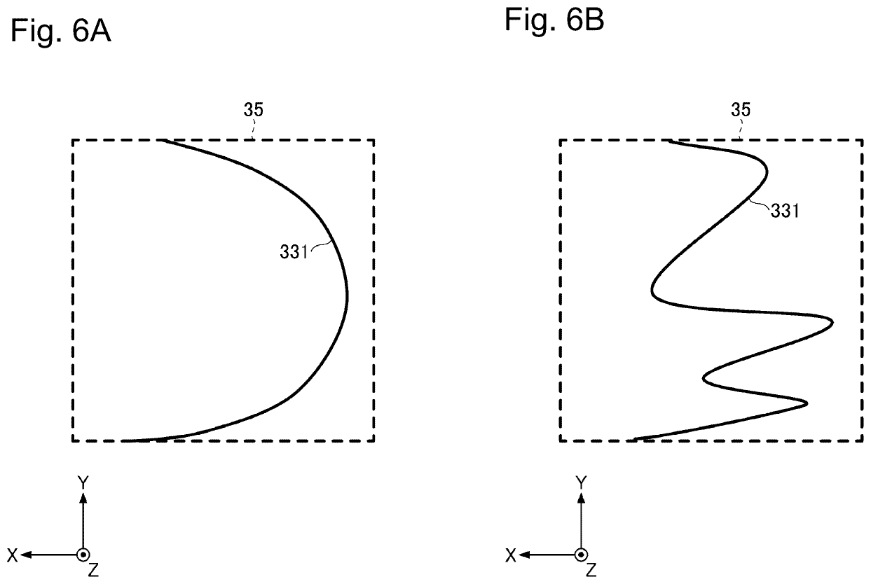

The configuration of the optical sensor cover 30A will be described with reference to FIGS. 5, 6A, and 6B. FIG. 5 is a front view of the optical sensor cover 30A. FIGS. 6A and 6B show diagrams showing examples of wiring segments 331 provided in the heating element 33A of the optical sensor cover 30A.

As shown in FIG. 5, the optical sensor cover 30A comprises a substrate 31, a heating element 33A, and electrodes 34a and 34b. The heating element 33A is a roughly circumferential member extending from the electrode 34a to the electrode 34b. The heating element 33A and the electrodes 34a and 34b are provided on the inner surface 31b of the substrate 31.

The electrodes 34a and 34b are respectively disposed at both ends of the heating element 33A. When the electrode 34a is a positive electrode and the electrode 34b is a negative electrode, an electric current flows from the electrode 34a to the electrode 34b through the heating element 33A. On the other hand, when the electrode 34a is a negative electrode and the electrode 34b is a positive electrode, an electric current flows from the electrode 34b to the electrode 34a through the heating element 33A. As an electric current flows through the heating element 33A, the heating element 33A generates heat. In this way, the substrate 31 is heated. The heating element 33A is formed of a conductive material such as gold, silver, copper, tin, aluminum, and an alloy using them.

Similarly to the first embodiment, the heating element 33A is formed of a plurality of wiring segments 331. Similarly to the first embodiment, the plurality of wiring segments 331 are partitioned from each other by using a plurality of imaginary square lattice cells 35 each having one side of 10 mm, arranged in the in-plane direction of the substrate 31.

For example, wiring segments 331 disposed at corners or the like of the heating element 33A formed in the circumferential shape have a relatively higher wiring density than those of the other wiring segments 331. As the wiring density increases, heat flows diffused from various parts of the wiring segments 331 overlap each other, and the heat-generating density of the peripheral area of the wiring segments 331 increases. That is, the peripheral area of wiring segments 331 having a geometrically high wiring density could become a hot spot.

As an example of wiring segments 331 having a high wiring density, wiring segments 331 having a configuration described below are referred to as “third wiring segments 331G”. The third wiring segment 331G (i.e., each of the third wiring segments) is a wiring segment 331 of which L′k/Lk is equal to or higher than 1.2, where L′k is the actual length of the third wiring segment 331G, and Lk is the coarse-graining length of the third wiring segment 331G. In the example shown in FIG. 5, wiring segments 331G1, 331G2, 331G3, 331G4, and 331G5 are examples of the third wiring segments 331G. Further, examples of the third wiring segments 331G also include those having at least one curved part. For example, a wiring segment 331 curved in an arc shape as shown in FIG. 6A and a wiring segment 331 having a plurality of curved parts and meandering as shown in FIG. 6B could be the third wiring segments 331G. The L′k/Lk of the third wiring segment 331G may be 10 or lower.

Further, the wiring segments 331 include “second wiring segments” in addition to the third wiring segments 331G. The second wiring segment (i.e., each of the second wiring segments) is, among the wiring segments 331 other than the third wiring segments 331G, a wiring segment 331 including no position at a distance of 20 mm or shorter from the edge 37 of the substrate 31, of which L′m/Lm is lower than 1.2, where L′m is the actual length of the second wiring segment, and Lm is the coarse-graining length of the second wiring segment. In the case of FIG. 5, wiring segments 331T1 and 331T2 correspond to the second wiring segments. Further, the second wiring segment is, when there is no wiring segment 331 including no position at a distance of 20 mm or shorter from the edge 37 of the substrate 31 among the wiring segments 331 other than the third wiring segments 331G (e.g., when the heating element 33 is wired so that there is no wiring segment 331T1 nor 331T2 shown in FIG. 5), a wiring segment 331 including a position farthest from the edge 37 of the substrate 31 among the wiring segments 331 other than the third wiring segments 331G, of which L′m/Lm is lower than 1.2. In this case, for example, a wiring segment 331T3 shown in FIG. 5 corresponds to the second wiring segment.

In this embodiment, the average resistance value of the third wiring segment 331G is a resistance value defined as “Rk/L′k” by using the resistance value Rk of the third wiring segment 331G and the actual length L′k of the third wiring segment 331G. Further, the average resistance value of the second wiring segment is a resistance value defined as “Rm/Lm” by using the resistance value Rm of the second wiring segment and the coarse-graining length Lm of the second wiring segment. The resistance value Rk of the third wiring segment 331G is obtained, for example, from the potential difference between both ends of the third wiring segment 331G and the electric current value of the electric current flowing through the third wiring segment 331G, measured at the wiring temperature of 20° C. to 30° C. Note that the potential difference between both ends of the third wiring segment 331G and the electric current value are obtained by specifying places corresponding to the positions of both ends of the third wiring segment 331G based on coordinate information such as the X and Y axis coordinates, and then measuring the potential difference between both specified places and the electric current value.

In this embodiment, the average resistance value Rk/L′k of 50% or more of all the third wiring segments 331G is lower than the average resistance value Rm/Lm of the second wiring segment. That is, in order to make the average resistance value of 50% or more of the third wiring segments 331G lower than the average resistance value Rm/Lm of the second wiring segment, the shape and the line width of the third wiring segments 331G are adjusted. The method for adjusting the shape and the line width of the third wiring segment 331G is arbitrarily determined. Its examples include a method for reducing the number of curved parts of the third wiring segments 331G, a method for reducing the wiring density by reducing the curvature of curved parts thereof, and a method for making the line width of the third wiring segments 331G larger than the average line width of the heating element 33A.

The average resistance value Rk/L′k of 50% or more of the third wiring segments 331G is preferably 0.01 to 0.99 times the average resistance value Rm/Lm, and more preferably 0.3 to 0.95 times the average resistance value Rm/Lm. By adjusting the relative value of the average resistance value Rk/L′k to the average resistance value Rm/Lm to the aforementioned range, it is possible to suppress the formation of a hot spot in the substrate 31 more effectively.

Note that the wiring segments 331 of which the heating element 33A is formed in the second embodiment may include the first wiring segments 331F of the first embodiment in addition to the third wiring segments 331G. Similarly, the wiring segments 331 of which the heating element 33 is formed in the first embodiment may include the third wiring segments 331G of the second embodiment in addition to the first wiring segments 331F.

### [Temperature Distribution Simulation]

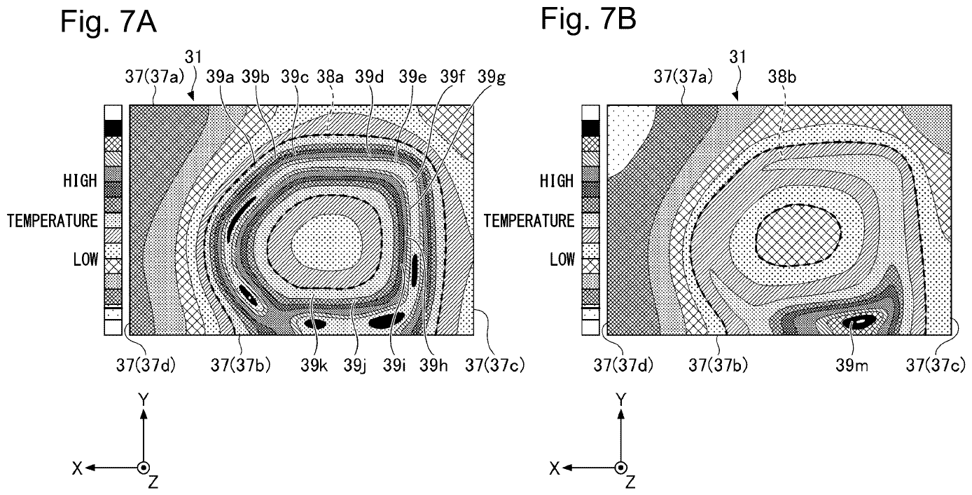

FIG. 7A shows a result of a similariton of a temperature distribution on the outer surface 31a of the substrate 31 in the first and second embodiments. For comparison, FIG. 7B shows a result of a similariton of a temperature distribution on an outer surface 31a of a substrate 31 including a heating element in related art.

An area 38a indicated by a broken line in FIG. 7A is an area including the heating element 33 or 33A. The temperature of the outer surface 31a of the substrate 31 decreases as the distance from the area 38a increases. An area 38b indicated by a broken line in FIG. 7B is an area including a heating element in related art. The temperature of the outer surface 31a of the substrate 31 decreases as the distance from the area 38b increases.

In the substrate 31 including a heating element in related art shown in FIG. 7B, the temperature of the area 39m and the vicinity thereof increases in the area 38b, and a hot spot where the temperature locally rises is formed. In contrast, in the substrates 31 of the first and second embodiments shown in FIG. 7A, a plurality of roughly annular areas 39a to 39k each having a uniform temperature are formed in the area 38a, so that the unevenness of the temperature is eliminated. Further, in the substrate 31 shown in FIG. 7A, high-temperature areas are widely distributed, so that it is possible to prevent condensation and the like from being formed or deposited in the effective area through which near-infrared light projected from the light projecting unit 21 and near-infrared light received by the light receiving unit 22 pass.

### Third Embodiment

An optical sensor 1B according to a third embodiment will be described. Note that in the third embodiment, components similar to those of the embodiments described above are denoted by the same reference numerals, and their descriptions will be omitted.

Similarly to the above-described embodiments, the optical sensor 1B according to the third embodiment comprises a housing 10 and an optical element including a light projecting unit 21 and a light receiving unit 22 (see FIG. 1). Similarly to the optical sensor covers 30 and 30A, an optical sensor cover 30B is a member for protecting the optical element housed in the housing 10. The linear heating element 33B (hereinafter simply referred to as a “heating element 33B”) in the optical sensor cover 30B is different from that in the above-described embodiments.

The configuration of the optical sensor cover 30B will be described with reference to FIG. 8. FIG. 8 is a front view of the optical sensor cover 30B. As shown in FIG. 8, the optical sensor cover 30B comprises a substrate 31, a heating element 33B, and electrodes 34a and 34b. The heating element 33B is a member having a folded structure including folded parts at a plurality of places from the electrode 34a to the electrode 34b. The heating element 33B and the electrodes 34a and 34b are provided, for example, on the inner surface 31b of the substrate 31.

The electrodes 34a and 34b are respectively disposed at both ends of the heating element 33B. When the electrode 34a is a positive electrode and the electrode 34b is a negative electrode, an electric current flows from the electrode 34a to the electrode 34b through the heating element 33B. On the other hand, when the electrode 34a is a negative electrode and the electrode 34b is a positive electrode, an electric current flows from the electrode 34b to the electrode 34a through the heating element 33B. As an electric current flows through the heating element 33B, the heating element 33B generates heat. As a result, the substrate 31 is heated. The heating element 33B is formed of a conductive material such as gold, silver, copper, tin, aluminum, and an alloy using them.

Similarly to the above-described embodiments, the heating element 33B is formed of a plurality of wiring segments 331. The plurality of wiring segments 331 are partitioned from each other by using a plurality of imaginary square lattice cells 35 each having one side of 10 mm, arranged in the in-plane direction of the substrate 31.

In this embodiment, the plurality of wiring segments 331 include wiring segments 331 disposed at a distance of 20 mm or shorter from the edge 37 of the substrate 31 and wiring segments 331 having a relatively higher wiring density than those of the other wiring segments 331. The heating element 33B in this embodiment includes, for example, three types of wiring segments 331 described below. The first type of wiring segments 331 corresponds to the first wiring segments 331F of the first embodiment. That is, this wiring segment 331 is a wiring segment 331 including a position at a distance of 20 mm or shorter from the edge 37 of the substrate 31, of which L′n/Ln is lower than 1.2, where L′n is the actual length, and Ln is the coarse-graining length. Further, the second type of wiring segments 331 corresponds to the third wiring segments 331G of the second embodiment. This wiring segment 331 is a wiring segments 331 of which L′k/Lk is equal to or higher than 1.2, where L′k is the actual length, and Lk is the coarse-graining length. These wiring segments are generically referred to as “wiring segments 331H”. In the example shown in FIG. 8, the wiring segments 331H1 to 331H26 correspond to the wiring segments 331H.

Further, the third type of wiring segments 331 corresponds to the second wiring segments of the first and second embodiments. That is, the second wiring segment (i.e., each of the second wiring segments) according to this embodiment is, among the wiring segments 331 other than the wiring segments 331H, a wiring segment 331 including no position at a distance of 20 mm or shorter from the edge 37 of the substrate 31, of which L′m/Lm is lower than 1.2, where L′m is the actual length of the second wiring segment, and Lm is the coarse-graining length of the second wiring segment. Further, the second wiring segment is, when there is no wiring segment 331 including no position at a distance of 20 mm or shorter from the edge 37 of the substrate 31 among the wiring segments 331 other than the wiring segments 331H, a wiring segment 331 including a position farthest from the edge 37 of the substrate 31 among the wiring segments 331 other than the wiring segments 331H, of which L′m/Lm is lower than 1.2.

In this embodiment, the average resistance value of each of the wiring segments 331H corresponding to the first wiring segments (e.g., wiring segments 331H1 to 331H6, 331H8, 331H10, 331H11, 331H13, and 331H15 to 331H26) among the wiring segments 331H is a resistance value defined as “Rp/Lp” by using the resistance value Rp of the wiring segment 331H and the coarse-graining length Lp of the wiring segment 331H. Further, the average resistance value of each of the wiring segments 331H corresponding to the third wiring segments (e.g., wiring segments 331H7, 331H9, 331H12, and 331H14) among the wiring segments 331H is a resistance value defined as “Rp/L′p” by using the resistance value Rp of the wiring segment 331H and the actual length L′p of the wiring segment 331H. The wiring segments 331H of which the average resistance value Rp/Lp or the average resistance value Rp/L′p of each of the wiring segments 331H is lower than the average resistance value Rm/Lm of the second wiring segment occupy 50% or more of all the wiring segments 331H. Note that the resistance value Rp is an example of the “resistance value Rn” or the “resistance value Rk”. The actual length L′p is an example of the “actual length L′n” or the “actual length L′k”. The average resistance value Rp/Lp is an example of the “average resistance value Rn/Ln”. The average resistance value Rp/L′p is an example of the “average resistance value Rk/L′k”.

The average resistance value Rp/Lp of the wiring segments 331H (i.e., the wiring segments 331H corresponding to the first wiring segments) lower than the average resistance value Rm/Lm of the second wiring segment is preferably 0.01 to 0.99 times the average resistance value Rm/Lm of the second wiring segment, and more preferably 0.3 to 0.95 times the average resistance value Rm/Lm of the second wiring segment. The average resistance value Rp/L′p of the wiring segments 331H (i.e., the wiring segments 331H corresponding to the third wiring segment) lower than the average resistance value Rm/Lm of the second wiring segment is preferably 0.01 to 0.99 times the average resistance value Rm/Lm of the second wiring segment, and more preferably 0.3 to 0.95 times the average resistance value Rm/Lm of the second wiring segment.

### [Simulation of Temperature Distribution]

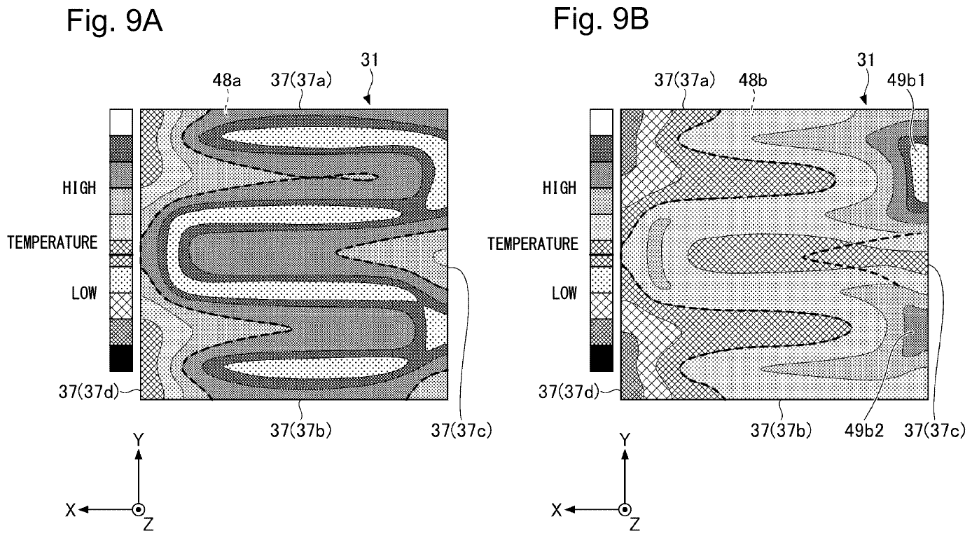

FIG. 9A shows a result of a similariton of a temperature distribution on the outer surface 31a of the substrate 31 in the third embodiment. For comparison, FIG. 9B shows a result of a similariton of a temperature distribution on an outer surface 31a of a substrate 31 including a heating element in related art.

An area 48a indicated by a broken line in FIG. 9A is an area including the heating element 33B. An area 48b indicated by a broken line in FIG. 9B is an area including a heating element in related art. As shown in FIG. 9A, an area having a high temperature is formed along the heating element 33B. Further, no hot spot where the temperature locally rises is formed. In contrast, as shown in FIG. 9B, in the heating element in related art, the temperatures of areas 49b1 and 49b2 located close to the edge 37 of the substrate 31 and including folded parts of the heating element are locally high. Further, in the substrate 31 shown in FIG. 9A, high-temperature areas are widely distributed, so that it is possible to prevent condensation and the like from being formed or deposited in the effective area through which near-infrared light projected from the light projecting unit 21 and near-infrared light received by the light receiving unit 22 pass.

Although preferred embodiments and the like have been described above in detail, the present invention is not limited to the above-described embodiments and the like, and various modifications and substitutions can be made to the above-described embodiments and the like without departing from the scope of the patent claims.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. An optical sensor cover comprising:
an optically-transparent substrate; and
a linear heating element provided in the substrate, wherein
the heating element comprises a plurality of wiring segments arranged in an in-plane direction of the substrate and partitioned by a plurality of imaginary square lattice cells each having one side of 10 mm,
the plurality of wiring segments include a first wiring segment and a second wiring segment,
the first wiring segment is a wiring segment including a position at a distance of 20 mm or shorter from an edge of the substrate, of which L′n/Ln is lower than 1.2, where L′n is an actual length of the first wiring segment, and Ln is a length of the first wiring segment measured with coarse graining of 10 mm,
the second wiring segment is, among wiring segments other than the first wiring segment, a wiring segment including no position at a distance of 20 mm or shorter from the edge of the substrate, of which L′m/Lm is lower than 1.2, where L′m is an actual length of the second wiring segment, and Lm is a length of the second wiring segment measured with coarse graining of 10 mm; or the second wiring segment is, when there is no wiring segment including no position at a distance of 20 mm or shorter from the edge of the substrate among the wiring segments other than the first wiring segment, a wiring segment including a position farthest from the edge of the substrate among the wiring segments other than the first wiring segment, of which L′m/Lm is lower than 1.2, and
when a resistance value of the first wiring segment is represented by Rn; an average resistance value of the first wiring segment is defined as Rn/Ln; a resistance value of the second wiring segment is represented by Rm; and an average resistance value of the second wiring segment is defined as Rm/Lm,
the average resistance value Rn/Ln of 50% or more of all first wiring segments is lower than the average resistance value Rm/Lm of the second wiring segment.

2. An optical sensor cover comprising:
an optically-transparent substrate; and
a linear heating element provided in the substrate, wherein
the heating element comprises a plurality of wiring segments arranged in an in-plane direction of the substrate and partitioned by a plurality of imaginary square lattice cells each having one side of 10 mm,
the plurality of wiring segments includes a third wiring segment and a second wiring segment,
the third wiring segment is a wiring segment of which L′k/Lk is equal to or higher than 1.2, where L′k is an actual length of the third wiring segment, and Lk is a length of the third wiring segment measured with coarse graining of 10 mm, and
the second wiring segment is, among wiring segments other than the third wiring segment, a wiring segment including no position at a distance of 20 mm or shorter from the edge of the substrate, of which L′m/Lm is lower than 1.2, where L′m is an actual length of the second wiring segment, and Lm is a length of the second wiring segment measured with coarse graining of 10 mm; or the second wiring segment is, when there is no wiring segment including no position at a distance of 20 mm or shorter from the edge of the substrate among the wiring segments other than the third wiring segment, a wiring segment including a position farthest from the edge of the substrate among the wiring segments other than the third wiring segment, of which L′m/Lm is lower than 1.2, and
when a resistance value of the third wiring segment is represented by Rk; an average resistance value of the third wiring segment is defined as Rk/L′k; a resistance value of the second wiring segment is represented by Rm; and an average resistance value of the second wiring segment is defined as Rm/Lm,
the average resistance value Rk/L′k of 50% or more of all third wiring segments is lower than the average resistance value Rm/Lm of the second wiring segment.

3. The optical sensor cover according to claim 1, wherein the first wiring segment includes at least one curved part.

4. The optical sensor cover according to claim 2, wherein the third wiring segment includes at least one curved part.

5. The optical sensor cover according to claim 1, wherein the average resistance value Rn/Ln of the first wiring segment is 0.3 to 0.95 times the average resistance value Rm/Lm of the second wiring segment.

6. The optical sensor cover according to claim 2, wherein the average resistance value Rk/L′k of the third wiring segment is 0.3 to 0.95 times the average resistance value Rm/Lm of the second wiring segment.

7. The optical sensor cover according to claim 1, wherein the first wiring segment includes an area having a line width larger than the average line width of the heating element.

8. The optical sensor cover according to claim 2, wherein the third wiring segment includes an area having a line width larger than the average line width of the heating element.

9. The optical sensor cover according to claim 1, wherein the heating element contains at least one of gold, silver, copper, tin, aluminum, and an alloy using them.

10. An optical sensor comprising:
a housing;
an optical element housed in the housing; and
an optical sensor cover attached to the housing so as to cover the optical element, wherein
the optical sensor cover comprises:
an optically-transparent substrate; and
a linear heating element provided in the substrate, wherein
the heating element comprises a plurality of wiring segments arranged in an in-plane direction of the substrate and partitioned by a plurality of imaginary square lattice cells each having one side of 10 mm,
the plurality of wiring segments include a first wiring segment and a second wiring segment,
the first wiring segment is a wiring segment including a position at a distance of 20 mm or shorter from an edge of the substrate, of which L′n/Ln is lower than 1.2, where L′n is an actual length of the first wiring segment, and Ln is a length of the first wiring segment measured with coarse graining of 10 mm,
the second wiring segment is, among wiring segments other than the first wiring segment, a wiring segment including no position at a distance of 20 mm or shorter from the edge of the substrate, of which L′m/Lm is lower than 1.2, where L′m is an actual length of the second wiring segment, and Lm is a length of the second wiring segment measured with coarse graining of 10 mm; or the second wiring segment is, when there is no wiring segment including no position at a distance of 20 mm or shorter from the edge of the substrate among the wiring segments other than the first wiring segment, a wiring segment including a position farthest from the edge of the substrate among the wiring segments other than the first wiring segment, of which L′m/Lm is lower than 1.2, and
when a resistance value of the first wiring segment is represented by Rn; an average resistance value of the first wiring segment is defined as Rn/Ln; a resistance value of the second wiring segment is represented by Rm; and an average resistance value of the second wiring segment is defined as Rm/Lm,
the average resistance value Rn/Ln of 50% or more of all first wiring segments is lower than the average resistance value Rm/Lm of the second wiring segment.

11. An optical sensor comprising:
a housing;
an optical element housed in the housing; and
an optical sensor cover attached to the housing so as to cover the optical element, wherein
the optical sensor cover comprises:
an optically-transparent substrate; and
a linear heating element provided in the substrate, wherein
the heating element comprises a plurality of wiring segments arranged in an in-plane direction of the substrate and partitioned by a plurality of imaginary square lattice cells each having one side of 10 mm,
the plurality of wiring segments includes a third wiring segment and a second wiring segment,
the third wiring segment is a wiring segment of which L′k/Lk is equal to or higher than 1.2, where L′k is an actual length of the third wiring segment, and Lk is a length of the third wiring segment measured with coarse graining of 10 mm, and;
the second wiring segment is, among wiring segments other than the third wiring segment, a wiring segment including no position at a distance of 20 mm or shorter from the edge of the substrate, of which L′m/Lm is lower than 1.2, where L′m is an actual length of the second wiring segment, and Lm is a length of the second wiring segment measured with coarse graining of 10 mm; or the second wiring segment is, when there is no wiring segment including no position at a distance of 20 mm or shorter from the edge of the substrate among the wiring segments other than the third wiring segment, a wiring segment including a position farthest from the edge of the substrate among the wiring segments other than the third wiring segment, of which L′m/Lm is lower than 1.2, and
when a resistance value of the third wiring segment is represented by Rk; an average resistance value of the third wiring segment is defined as Rk/L′k; a resistance value of the second wiring segment is represented by Rm; and an average resistance value of the second wiring segment is defined as Rm/Lm,
the average resistance value Rk/L′k of 50% or more of all third wiring segments is lower than the average resistance value Rm/Lm of the second wiring segment.

12. The optical sensor according to claim 10, wherein
the housing is made of resin or metal, and
when the housing is made of metal, a heat insulating material is provided between the housing and the substrate.

13. The optical sensor according to claim 10, wherein
the optical sensor is a range sensor, and
the optical element comprises a light projecting unit, and a light receiving unit configured to receive reflected light, the reflected light being light projected from the light projecting unit and reflected on an object.
